(19) United States
(12) Patent Application Publication
(10) Pub. No.: US 2022/0085219 A1
(43) Pub. Date: Mar. 17, 2022

(54) PHOTOVOLTAIC DEVICES INCLUDING FLEXIBLE BYPASS DIODE CIRCUIT

(71) Applicant: Utica Leaseco, LLC, Rochester Hills, MI (US)

(72) Inventors: James G. NEFF, Felton, CA (US); Paul E. SIMS, Sunnyvale, CA (US)

(21) Appl. No.: 17/474,884

(22) Filed: Sep. 14, 2021

Related U.S. Application Data
(60) Provisional application No. 63/078,011, filed on Sep. 14, 2020.

(51) Int. Cl. H01L 31/02; H01L 31/05; H01L 31/18

(52) U.S. Cl. CPC H01L 31/02021; H01L 31/186; H01L 31/05

(57) ABSTRACT

A photovoltaic device may include a flexible diode circuit having one or more bypass diodes mounted to one or more semiconductor layers using surface mount technology (SMT). The bypass diode and the one or more of the semiconductor layers may allow the flexible diode circuit to be manufactured as a thin, flexible ribbon, thereby providing efficiency in manufacturing and storing of the flexible diode circuit and/or the photovoltaic device, and also increasing a packing factor and areal power of the photovoltaic device, as compared to a typical photovoltaic device.

### CROSS-REFERENCE TO RELATED APPLICATION(S)

This application claims the benefit of U.S. Provisional Application No. 63/078,011, entitled “Photovoltaic Devices Including Flexible Bypass Diode Circuit” and filed on Sep. 14, 2020, which is expressly incorporated by reference herein in its entirety.

### BACKGROUND

### Technical Field

The present disclosure relates generally to photovoltaic devices, such as solar cells, and methods of manufacturing such photovoltaic devices.

### INTRODUCTION

Photovoltaic devices, such as solar cells or solar panels, harness energy from the sun to generate a voltage, thereby converting light energy to electric energy. The generated voltage can be increased by connecting photovoltaic devices in series, and the current may be increased by connecting photovoltaic devices in parallel. Photovoltaic devices may be grouped together in modules to form solar panels.

Photovoltaic devices may include materials and components that may result in flexibility and electrical protection to the photovoltaic cells and the photovoltaic devices. However, some of these materials and components may require a relatively large amount of area in typical photovoltaic devices in order to provide these benefits. Further, materials and components used by typical photovoltaic devices may unnecessarily add to the overall cost and time of production of photovoltaic devices.

Accordingly, there exists a need for further improvements to photovoltaic devices and the manufacturing thereof.

### SUMMARY

The following presents a simplified summary of one or more aspects in order to provide a basic understanding of such aspects. This summary is not an extensive overview of all contemplated aspects, and is intended to neither identify key or critical elements of all aspects nor delineate the scope of any or all aspects. Its sole purpose is to present some concepts of one or more aspects in a simplified form as a prelude to the more detailed description that is presented later.

In an aspect, a photovoltaic device is presented. The photovoltaic device may include a matrix of photovoltaic cells having a plurality of sets of photovoltaic cells coupled in series. The photovoltaic device may also include a flexible diode circuit. The flexible diode circuit may include a plurality of bypass diodes configured to provide electrical protection for the matrix of photovoltaic cells, wherein each bypass diode of the plurality of bypass diodes corresponds to a respective set of photovoltaic cells of the plurality of sets of photovoltaic cells and is coupled in parallel with the respective set of photovoltaic cells. The flexible diode circuit may also include a flexible layer configured to provide a flexible base and interconnect for the plurality of bypass diodes to couple with the plurality of sets of photovoltaic cells, wherein the plurality of bypass diodes are surface mounted to the flexible layer.

In another aspect, a method for forming a flexible diode circuit is presented. The method may include forming a flexible substrate layer. The method may also include providing a conductive layer over the flexible substrate layer. The method may also include coupling one or more bypass diodes to the conductive layer.

In another aspect, a method for forming a photovoltaic device is presented. The method may include connecting a plurality of photovoltaic cells in series to form a matrix of photovoltaic cells. The method may also include attaching one or more strips of a flexible diode circuit to the matrix of photovoltaic cells, the flexible diode circuit including a plurality of bypass diodes configured to provide electrical protection for the matrix of photovoltaic cells. The method may also include electrically coupling each of the plurality of bypass diodes to a respective set of photovoltaic cells of the matrix of photovoltaic cells.

To the accomplishment of the foregoing and related ends, the one or more aspects comprise the features hereinafter fully described and particularly pointed out in the claims. The following description and the annexed drawings set forth in detail certain illustrative features of the one or more aspects. These features are indicative, however, of but a few of the various ways in which the principles of various aspects may be employed, and this description is intended to include all such aspects and their equivalents.

### BRIEF DESCRIPTION OF THE DRAWINGS

The disclosed aspects will hereinafter be described in conjunction with the appended drawings, provided to illustrate and not to limit the disclosed aspects, wherein like designations denote like elements, and in which:

FIG. 1A illustrates an example of a photovoltaic device;

FIG. 1B illustrates an example of a photovoltaic device, according to aspects of the present disclosure;

FIG. 2 illustrates an example of a photovoltaic device having a flexible diode circuit, according to aspects of the present disclosure;

FIG. 3 illustrates an example of the flexible diode circuit of FIG. 2, according to aspects of the present disclosure;

FIG. 4 illustrates another example of the flexible diode circuit of FIG. 2, according to aspects of the present disclosure;

FIG. 5 illustrates another example of a photovoltaic device having a flexible diode circuit, according to aspects of the present disclosure;

FIG. 6 illustrates a flowchart of an example of a method of forming a flexible diode circuit, according to aspects of the present disclosure; and

FIG. 7 illustrates a flowchart of an example of a method of forming a photovoltaic device, according to aspects of the present disclosure.

### DETAILED DESCRIPTION

The detailed description set forth below in connection with the appended drawings is intended as a description of various configurations and is not intended to represent the only configurations in which the concepts described herein may be practiced. The detailed description includes specific details for the purpose of providing a thorough understanding of various concepts. However, it will be apparent to those skilled in the art that these concepts may be practiced without these specific details. In some instances, well known structures and components are shown in block diagram form in order to avoid obscuring such concepts.

A typical photovoltaic device may include a bypass protection metal ribbon comprising a tin (Sn)-coated copper (Cu) ribbon and a diode, such as a Schottky protection diode. As the Sn-coated Cu ribbon is conductive, the metal ribbon may be separated from photovoltaic cells in order to avoid an electrical short at the edges of the photovoltaic cells. In an example, a width of the metal ribbon width may be around 5 millimeters (mm) and the separation between the metal ribbon and the photovoltaic cells may be 2-3 mm, resulting in an increased width of 7-8 mm of the photovoltaic device. The increased width may equate to about a 4% footprint of the overall footprint of the photovoltaic device, thereby reducing the packing factor (e.g., reduced package size) and areal power (e.g., surface power density) of the photovoltaic device. Due to the size of the metal ribbon, an amount of area of light capture on the photovoltaic device may be reduced and, in some cases, an amount of aerodynamic drag may be increased.

The present disclosure provides a photovoltaic device having a flexible diode circuit. The flexible diode circuit may include one or more bypass diodes mounted to one or more semiconductor layers using surface mount technology (SMT). The bypass diode and the one or more of the semiconductor layers, as disclosed herein, may allow the flexible diode circuit to be manufactured as a thin, flexible ribbon, thereby providing efficiency in manufacturing and storing of the flexible diode circuit and/or the photovoltaic devices, and also increasing the packing factor and the areal power of the photovoltaic device, as compared to the typical photovoltaic device.

Turning now to the figures, examples of photovoltaic devices and methods of manufacturing the photovoltaic devices are described herein. It is to be understood that layers and components in the figures may not be drawn to scale and are instead drawn for illustrative purposes.

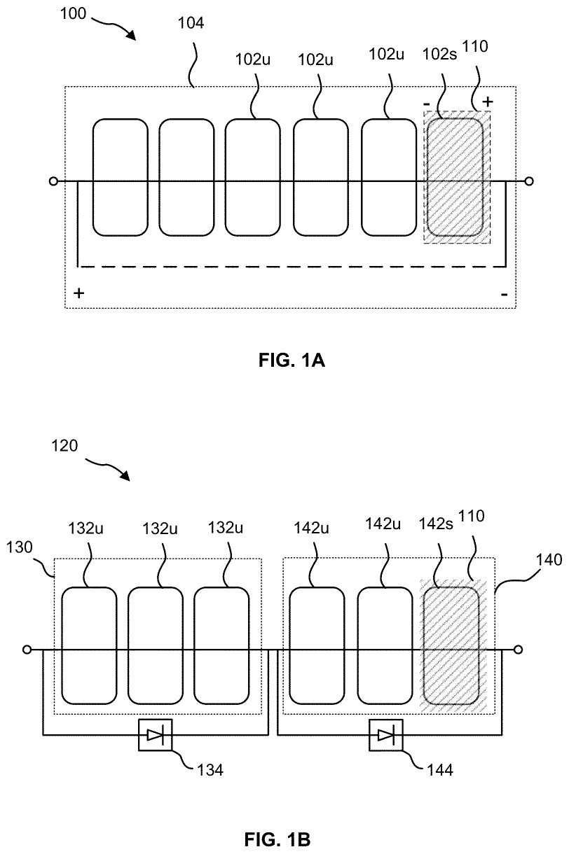

FIGS. 1A and 1B illustrate examples of photovoltaic devices 100, 120, including a plurality of photovoltaic cells. For purposes of these examples, a photovoltaic cell covered by shade 110 is referenced with an “s” for shaded (e.g., 102s, 132s, 142s), a photovoltaic cell that is not covered by the shade 110 is referenced with a “u” for unshaded (e.g., 102u, 132u, 142u), and any one or more of the photovoltaic devices (shaded or unshaded) are referenced without any designation (e.g., 102, 132, 142).

Referring to FIG. 1A, an example of the photovoltaic device 100 is depicted. The photovoltaic device 100 may include one or more photovoltaic cells 102 connected in series in a string in a module 104 (or string) to provide increased power and voltage from sunlight. In some instances, an obstruction may cause shade 110 to cover a portion (e.g., one or more photovoltaic cells) of the photovoltaic cells 102 during operation of the photovoltaic device 100. The shade 110 may affect performance of the entire module 104 and/or the photovoltaic device 100. In an example, a series mismatch may occur when electrical parameters of one photovoltaic cell (e.g., photovoltaic cell 102s) are significantly altered from those of the other photovoltaic cells (e.g., photovoltaic cells 102u). Since current through each of the photovoltaic cells 102 must be substantially the same, the overall current from the combination of photovoltaic cells 102 may not exceed that of the shaded photovoltaic cell 102s. At low voltages, when the shade 110 covers the photovoltaic cell 102s while the remaining photovoltaic cells 102u in the module 104 are not shaded, the current being generated by the unshaded photovoltaic cells 102u may be dissipated in the shaded photovoltaic cell 102s rather than powering a load (not shown). Thus, in a series connected configuration with a current mismatch, severe power reductions may occur if the shaded photovoltaic cell 102s produces less current than the remaining photovoltaic cells 102u. If the configuration is operated at short circuit or low voltages, the highly localized power dissipation in the shaded photovoltaic cell 102s may cause local “hot spot” heating, avalanche breakdown, and/or irreversible damage to the photovoltaic device 100.

Referring to FIG. 1B, an example of the photovoltaic device 120, according to aspects of the present disclosure, is depicted. The photovoltaic device 120 may include high performance photovoltaic cells, such as gallium arsenide (GaAs) photovoltaic cells. The photovoltaic device 120 may use a bypass function to prevent local “hot spot” heating, avalanche breakdown, and/or damage to photovoltaic device 120. For example, as shown in FIG. 1B, the photovoltaic device 120 may include a first set 130 (or group) of photovoltaic cells 132 that are attached to a bypass diode 134, and a second set 140 of photovoltaic cells 142 that are attached to a bypass diode 144. Each of the bypass diodes 134, 144 may be connected in parallel and with opposite polarity to the respective photovoltaic cells 132, 142.

In an example, during operation of the photovoltaic device 120, each of the photovoltaic cells 132 of the first set 130 are forward biased and the bypass diode 134 is reverse biased because none of the photovoltaic cells 132u are covered by the shade 110. As a result, the bypass diode 124 creates an open circuit and the first set 130 operates according to a normal operation. In contrast, during operation of the photovoltaic device 120, the one or more of the photovoltaic cells 142s of the second set 140 that are covered by the shade 110 may be reverse biased due to a mismatch in short-circuit current between series connected photovoltaic cells 142, and the bypass diode 144 may be forward biased and conduct current. As a result, the current from the unshaded photovoltaic cells 142u may flow in through the bypass diode 144 rather than forward biasing each of the unshaded photovoltaic cells 142u. The maximum reverse bias across the shaded photovoltaic cell 142s may be reduced to around a single diode drop, thereby limiting the current and preventing hot-spot heating and damage to the photovoltaic cells 142 of the second set 140.

Although bypass diodes (e.g., bypass diodes 134, 144) may be effective in reducing the destructive effects of mismatches in photovoltaic cells (e.g., photovoltaic cells 132, 142) due to shading, typical bypass diodes may add to the overall cost and time of production of photovoltaic devices (e.g., photovoltaic device 120) and may also require a relatively significant amount of area of the overall photovoltaic device.

The present disclosure describes examples of photovoltaic devices, according to aspects of the present disclosure, that provide a bypass function through the use of bypass protection flexible diode circuits and methods of manufacturing these photovoltaic devices. The examples of the photovoltaic devices disclosed herein may result in protection of the photovoltaic devices along with a reduction in cost of manufacturing and overall size of the photovoltaic devices, as compared to typical photovoltaic devices having metal ribbons.

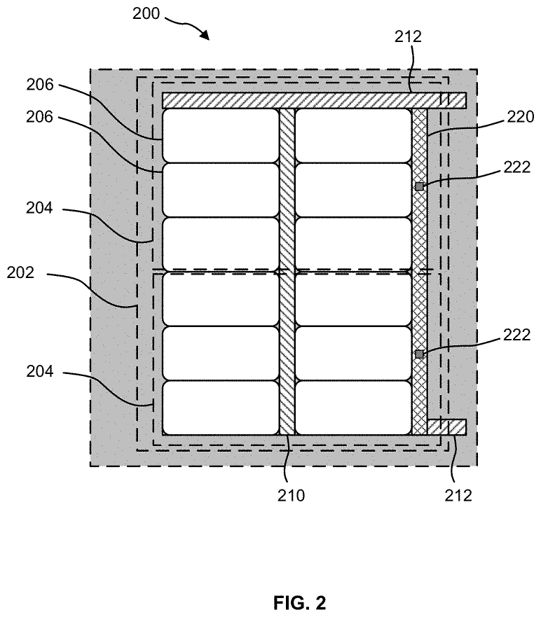

Referring to FIG. 2, an example of a photovoltaic device 200 is depicted. The photovoltaic device 200 may include a matrix of photovoltaic cells 202. The matrix of photovoltaic cells 202 may be organized into a plurality of sets of photovoltaic cells 204, where each of the sets of the photovoltaic cells 204 includes a plurality of photovoltaic cells 206 coupled in series with each other and each of the sets of photovoltaic cells 204 are coupled in series with each other. Examples of the photovoltaic cells 206 may include the photovoltaic cells 102, 132, and/or 142, disclosed herein.

The matrix of photovoltaic cells 202 may be coupled with one or more columns of interconnect ribbons 210 and/or one or more rows of interconnect ribbons 212. The interconnect ribbons 210, 212 may include one or more wires for coupling the each of the sets of photovoltaic cells 204 in series, and/or coupling the photovoltaic device 200 with other photovoltaic devices to form, for example, a solar panel.

The photovoltaic device 200 may also include a flexible diode circuit 220, which includes a plurality of bypass diodes 222 coupled in parallel (as shown by FIG. 1B) with respective sets of photovoltaic cells 204. Each of the bypass diodes 222 may protect the photovoltaic device 200 in a case of shade covering one or more of the photovoltaic cells 206, as described herein. Examples of the bypass diode 222 may include bypass diode 134 or 144. An example of the bypass diode 222 may include a surface-mount device (SMD).

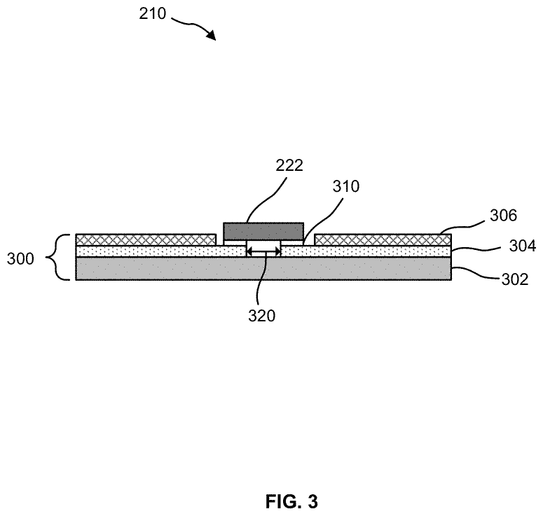

Referring to FIG. 3, an example of the flexible diode circuit 220 is depicted. The flexible diode circuit 220 may be a thin, narrow, patterned flex-circuit ribbon to enable mounting of the bypass diodes 222 using surface-mount technology (SMT). While FIG. 3 depicts the flexible diode circuit 220 only including a single bypass diode 222, aspects of the present disclosure are not limited in the number of bypass diodes 222 that the flexible diode circuit 220 may include.

The flexible diode circuit 220 may include a flexible layer 300 to provide a flexible base and interconnect for the bypass diodes 222 to electrically couple with other portions, such as the interconnect ribbons 210, 212 and the respective set of photovoltaic cells 204 of the photovoltaic device 200. The flexible layer 300 may include one or more layers including a flexible substrate layer 302, a conductive layer 304, and an insulation layer 306.

In an aspect, the flexible substrate layer 302 may form the base of the flexible layer 300 and the flexible diode circuit 220. In an example, the flexible substrate layer 302 may be formed of a flexible substrate material, depending on the application of the photovoltaic device 200.

In an aspect, the conductive layer 304 may be provided over the flexible substrate layer 302 and configured to electrically couple the bypass diode 222 with the respective set of photovoltaic cells 204 and/or other photovoltaic devices. In some examples, the conductive layer 304 may be deposited on the flexible substrate layer 302 and form a gap 320 that is bridged by the bypass diode 222. In particular, the bypass diode 222 may couple two portions of the conductive layer 304 via electrical connectors 310, which may include connecting wires, terminals, leads, solder, or other connecting materials used for mounting the bypass diode 222 to the conductive layer 304. The conductive layer 304 may be formed of an electrically conductive material, such as a metal or metal alloy. Some examples of the electrically conductive material may include gold (Au), copper (Cu), silver (Ag), aluminum (Al), palladium (Pd), platinum (Pt), titanium (Ti), zirconium (Zr), nickel (Ni), chromium (Cr), tungsten (W), tantalum (Ta), ruthenium (Ru), zinc (Zn), germanium (Ge), and/or derivatives, alloys, or combinations thereof.

In an aspect, the insulation layer 306 may be provided over the conductive layer 304 and allow the flexible diode circuit 220 to be substantially close to the set of photovoltaic cells 204. In other words, the insulation layer 306 may eliminate or substantially reduce a need for a space (or gap) between the flexible diode circuit 220 and an edge of the matrix of photovoltaic cells 202, as is needed by a typical metal ribbon. In some examples, the insulation layer 306 may be deposited on the conductive layer 304, as shown by FIG. 3. In an example, the insulation layer 306 may be formed of an insulating material such as silicon dioxide (SiO₂).

Due to the reduced size of the bypass diodes 222 incorporated into the flexible diode circuit 220 and the materials used to form the flexible layer 300, the flexible diode circuit 220 may result in an increase in packing factor and areal power of the photovoltaic device 200, in comparison with typical photovoltaic devices.

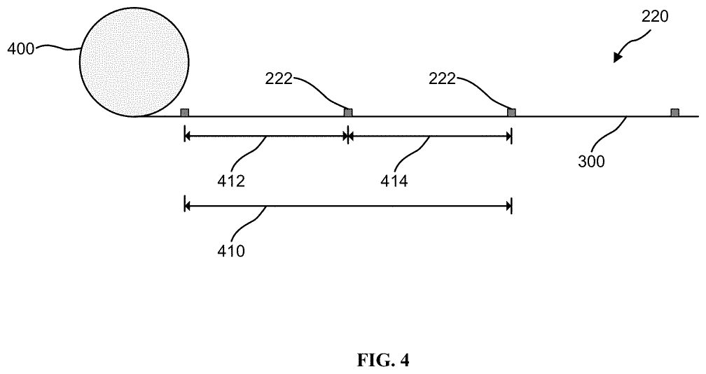

Referring to FIG. 4, an example of a reel 400 of the flexible diode circuit 220 is depicted. As the flexible diode circuit 220 is flexible, the flexible diode circuit 220 may be manufactured in long lengths and stored on the reel 400 to allow for more efficient manufacturing of the photovoltaic device 200. For example, during manufacturing of the photovoltaic device 200, one or more portions of the flexible diode circuit 220 may be extended from the reel 400 and cut to one or more predetermined lengths corresponding to the design needs of the photovoltaic device 200. Alternatively, the reel 400 may store the flexible diode circuit 220 at pre-cut lengths, meaning one or more predetermined lengths of the flexible diode circuit 220 are cut during or after manufacturing of the flexible diode circuit 220, and stored on the reel 400 in strips. In an example, during manufacturing of the photovoltaic device 200, the predetermined lengths may correspond to the distance between the interconnect ribbons 210, 212.

While FIGS. 2 and 3 illustrate the flexible diode circuit 220 comprising a single bypass diode, aspects of the present disclosure are not limited to a single bypass diodes. Instead, as shown by FIG. 4, the flexible diode circuit 220 may include a plurality of bypass diodes 222. The bypass diodes 222 may be separated on the flexible layer 300 according to a diode placement pattern 410, including a plurality of placement distances between any two diode bypass diodes 222. The diode placement pattern 410 may be determined based on the design and fit of the photovoltaic device 200. In an example, the plurality of placement distances may include a first placement distance 412 and a second placement distance 414. In some examples, the first placement distance 412 may be equal the second placement distance 414. In some examples, the first placement distance 412 may be different from the second placement distance 414. In an example, the bypass diodes 222 may have a diode placement pattern 410 between each of the bypass diodes 222 according to a standard, such as a 6, 8, or 11 cell maximum diode spacing, which may be based on photovoltaic product requirements of the photovoltaic device 200. In other words, the flexible diode circuit 220 may be manufactured for the spacing to be according to a standard “maximum diode spacing” requirement, in order for efficient photovoltaic device 200 manufacturing.

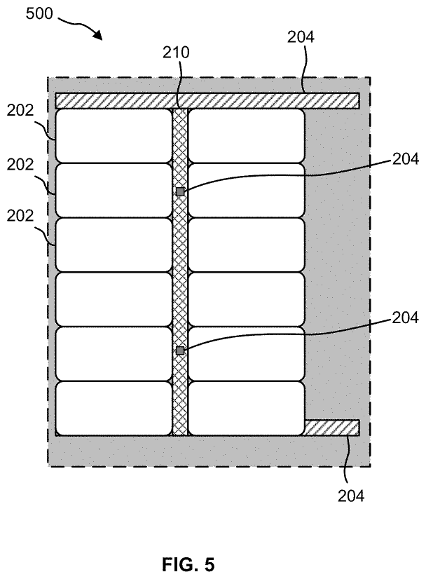

Referring to FIG. 5, another example of a photovoltaic device 500 is depicted. In this arrangement, the photovoltaic device 500 may be sufficiently narrowed (e.g., less than 1 millimeter (mm) wide) to be placed between a column gap of the matrix of photovoltaic cells 202, as illustrated by FIG. 5. This arrangement may further improve the packing factor and areal power of the photovoltaic device 500, as compared to the typical photovoltaic device.

Manufacturing

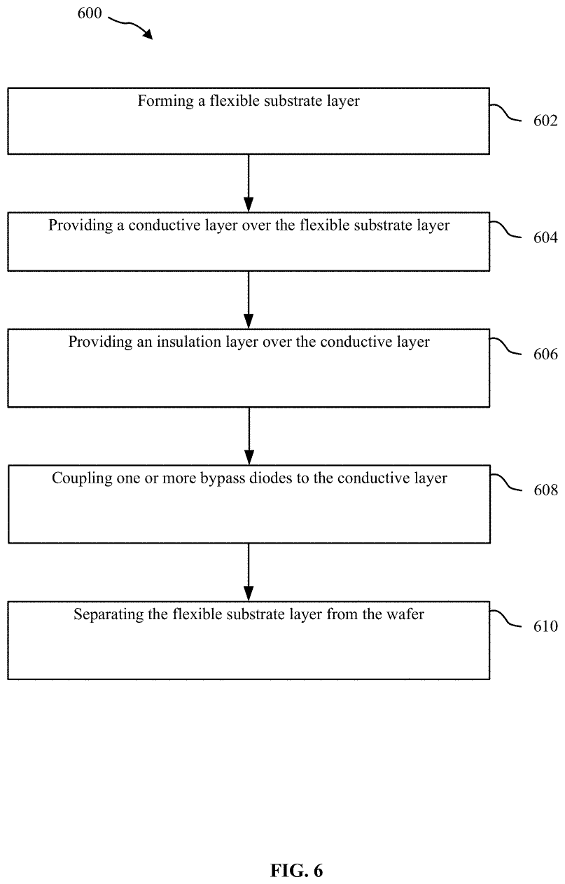

Referring to FIG. 6, an example of a method 600 for forming a flexible layer of a photovoltaic device, according to aspects of the present disclosure, is depicted. At 602, the method 600 may include forming a flexible substrate layer.

At 604, the method 600 may include providing a conductive layer over the flexible substrate layer. For example, as shown by FIG. 3, the conductive layer 304 may deposited on the flexible substrate layer 302.

At 606, the method 600 may optionally include providing an insulation layer over the conductive layer. For example, as shown by FIG. 3, the insulation layer 306 may be deposited on the conductive layer 304.

At 608, the method 600 may include coupling one or more bypass diodes to the conductive layer. For example, as shown by FIG. 3, the bypass diode 222 may couple with the conductive layer 304 via one or more connectors 310. In some examples, the bypass diode 222 may couple with the conductive layer 304 by way of contact of pins/leads on the bypass diode 222 with the conductive layer 304, soldering the pins/leads to the conductive layer 304, or any other method used for surface mount technology. As depicted by FIG. 4, a bypass diode 222 may be spaced from another bypass diode 222 according to the diode placement pattern 410.

At 610, the method 600 may optionally include separating the flexible substrate layer from the wafer. For example, if the flexible substrate layer 302 was grown on a wafer, the flexible substrate layer 302 may be separated from the wafer via one or more separation methods including cutting, etching, implant-cleave, or stress liftoff methods.

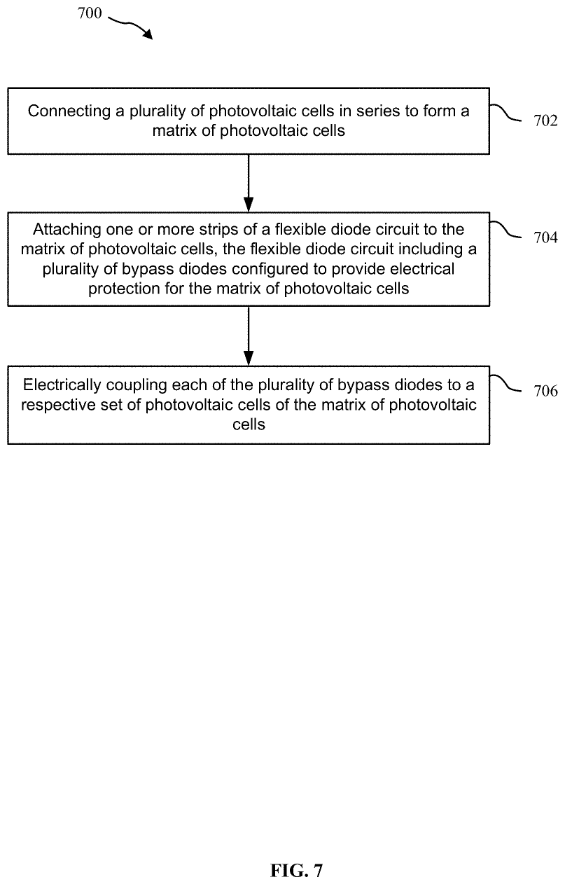

Referring to FIG. 7, an example of a method 700 for forming a photovoltaic device, according to aspects of the present disclosure, is depicted. At 702, the method 700 may include connecting a plurality of photovoltaic cells in series to form a matrix of photovoltaic cells. For example, the photovoltaic cells 206 may be coupled in series to form the matrix of photovoltaic cells 202.

At 704, the method 700 may include attaching one or more strips of a flexible diode circuit to the matrix of photovoltaic cells, the flexible diode circuit including a plurality of bypass diodes configured to provide electrical protection for the matrix of photovoltaic cells. For example, one or more strips of a flexible diode circuit 220 may be attached to the matrix of photovoltaic cells 202.

At 706, the method 700 may include electrically coupling each of the plurality of bypass diodes to a respective set of photovoltaic cells of the matrix of photovoltaic cells. For example, each of the bypass diodes 222 may electrically couple with a respective set of photovoltaic cells 204.

It is understood that the specific order or hierarchy of blocks in the processes/flowcharts disclosed is an illustration of exemplary approaches. Based upon different implementations, it is understood that the specific order or hierarchy of blocks in the processes/flowcharts may be rearranged. Further, some blocks may be combined or omitted. The accompanying method claims present elements of the various blocks in a sample order, and are not meant to be limited to the specific order or hierarchy presented.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but is to be accorded the full scope consistent with the language claims, wherein reference to an element in the singular is not intended to mean “one and only one” unless specifically so stated, but rather “one or more.” The word “exemplary” is used herein to mean “serving as an example, instance, or illustration.” Any aspect described herein as “exemplary” is not necessarily to be construed as preferred or advantageous over other aspects. Unless specifically stated otherwise, the term “some” refers to one or more. Combinations such as “at least one of A, B, or C,” “one or more of A, B, or C,” “at least one of A, B, and C,” “one or more of A, B, and C,” and “A, B, C, or any combination thereof” include any combination of A, B, and/or C, and may include multiples of A, multiples of B, or multiples of C. Specifically, combinations such as “at least one of A, B, or C,” “one or more of A, B, or C,” “at least one of A, B, and C,” “one or more of A, B, and C,” and “A, B, C, or any combination thereof” may be A only, B only, C only, A and B, A and C, B and C, or A and B and C, where any such combinations may contain one or more member or members of A, B, or C. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. The words “module,” “mechanism,” “element,” “device,” and the like may not be a substitute for the word “means.” As such, no claim element is to be construed as a means plus function unless the element is expressly recited using the phrase “means for.”

What is claimed is:

1. A photovoltaic device, comprising:
a matrix of photovoltaic cells having a plurality of sets of photovoltaic cells coupled in series; and
a flexible diode circuit including:
a plurality of bypass diodes configured to provide electrical protection for the matrix of photovoltaic cells, wherein each bypass diode of the plurality of bypass diodes corresponds to a respective set of photovoltaic cells of the plurality of sets of photovoltaic cells and is coupled in parallel with the respective set of photovoltaic cells; and
a flexible layer configured to provide a flexible base and interconnect for the plurality of bypass diodes to couple with the plurality of sets of photovoltaic cells, wherein the plurality of bypass diodes are surface mounted to the flexible layer.

2. The photovoltaic device of claim 1, wherein the plurality of bypass diodes are mounted to the flexible layer via surface mount technology.

3. The photovoltaic device of claim 1, wherein the flexible layer includes:
a flexible substrate layer to form the flexible base of the flexible layer.

4. The photovoltaic device of claim 3, wherein the flexible layer further includes:
a conductive layer formed over the flexible substrate layer and configured to electrically couple with the plurality of bypass diodes.

5. The photovoltaic device of claim 4, wherein the conductive layer is formed of one or more electrically conductive materials.

6. The photovoltaic device of claim 5, wherein the one or more electrically conductive materials include a metal or a metal alloy.

7. The photovoltaic device of claim 4, wherein the flexible layer further includes:
an insulation layer formed over the conductive layer and configured to insulate the plurality of bypass diodes from the matrix of photovoltaic cells.

8. The photovoltaic device of claim 7, wherein the insulation layer is formed of silicon dioxide (SiO₂).

9. The photovoltaic device of claim 1, wherein the flexible diode circuit couples with an edge of the matrix of photovoltaic cells.

10. The photovoltaic device of claim 1, wherein the flexible diode circuit couples with the matrix of photovoltaic cells between two columns of photovoltaic cells of the matrix of photovoltaic cells.

11. The photovoltaic device of claim 1, wherein each of the plurality of bypass diodes is mounted at a predetermined distance from another bypass diode.

12. The photovoltaic device of claim 11, wherein each of the plurality of bypass diodes is mounted at a maximum diode distance from the another bypass diode based on a design of the photovoltaic device.

13. The photovoltaic device of claim 1, wherein the flexible diode circuit has a width less than 1 millimeter.

14. A method for forming a flexible diode circuit, comprising:
forming a flexible substrate layer;
providing a conductive layer over the flexible substrate layer; and
coupling one or more bypass diodes to the conductive layer.

15. The method of claim 14, further comprising:
providing an insulation layer over the conductive layer.

16. A method for forming a photovoltaic device, comprising:
connecting a plurality of photovoltaic cells in series to form a matrix of photovoltaic cells;
attaching one or more strips of a flexible diode circuit to the matrix of photovoltaic cells, the flexible diode circuit including a plurality of bypass diodes configured to provide electrical protection for the matrix of photovoltaic cells; and
electrically coupling each of the plurality of bypass diodes to a respective set of photovoltaic cells of the matrix of photovoltaic cells.

17. The method of claim 16, wherein the flexible diode circuit comprises:
a flexible layer configured to provide a flexible base and interconnect for the plurality of bypass diodes to couple with the respective set of photovoltaic cells, wherein the plurality of bypass diodes are surface mounted to the flexible layer.

18. The method of claim 16, wherein the one or more strips of the flexible diode circuit are attached at an edge of the matrix of photovoltaic cells.

19. The method of claim 16, further comprising:
laminating the matrix of photovoltaic cells and the one or more strips of the flexible diode circuit.
